(19) United States
(12) Patent Application Publication
(10) Pub. No.: US 2026/0352250 A1
(43) Pub. Date: Nov. 5, 2026

(54) RADIO FREQUENCY MODULE AND COMMUNICATION DEVICE

(71) Applicant: Murata Manufacturing Co., Ltd., Nagaokakyo-shi (JP)

(72) Inventors: Kunitoshi HANAOKA, Nagaokakyo-shi (JP); Masakazu TANI, Nagaokakyo-shi (JP)

(73) Assignee: Murata Manufacturing Co., Ltd., Nagaokakyo-shi (JP)

(21) Appl. No.: 19/655,771

(22) Filed: Apr. 23, 2026

(30) Foreign Application Priority Data
May 1, 2025 (JP) 2025-076163

(51) Int. Cl. H04B 1/40; H03F 3/195; H03H 9/25; H03H 9/64

(52) U.S. Cl. CPC H04B 1/40; H03F 3/195; H03H 9/25; H03H 9/6483; H03F 2200/451

(57) ABSTRACT

A radio frequency module includes a first acoustic wave filter that has a first input section and a first output section, a low-noise amplifier that has an input section and an output section, the input section of the low-noise amplifier being connected to the first output section of the first acoustic wave filter, a second acoustic wave filter that has a second input section and a second output section, the second input section of the second acoustic wave filter being connected to the output section of the low-noise amplifier, and a capacitor connected to the second output section of the second acoustic wave filter.

### CROSS-REFERENCE TO RELATED APPLICATION

This application claims priority to Japanese Patent Application No. 2025-076163, filed on May 1, 2025. The entire contents of the above-listed application are incorporated herein by reference.

### BACKGROUND

### 1. Field

The present disclosure generally relates to a radio frequency module and a communication device, and more particularly, to a radio frequency module including a low-noise amplifier and a communication device including the radio frequency module.

### 2. Description of the Related Art

A front-end circuit described in Japanese Unexamined Patent Application Publication No. 2021-125775 includes a multiplexer, having multiple filters, and a low-noise amplifier. The low-noise amplifier is connected, at its input section, to an output section of one of the filters. The low-noise amplifier is connected, at its output section, to a radio frequency integrated circuit (RFIC) external to the front-end circuit.

### SUMMARY

A radio frequency module according to an aspect of the present disclosure includes a first acoustic wave filter that has a first input section and a first output section, a low-noise amplifier that has an input section and an output section, the input section of the low-noise amplifier being connected to the first output section of the first acoustic wave filter, a second acoustic wave filter that has a second input section and a second output section, the second input section of the second acoustic wave filter being connected to the output section of the low-noise amplifier, and a capacitor connected to the second output section of the second acoustic wave filter.

### BRIEF DESCRIPTION OF THE DRAWINGS

FIG. 1 is a diagram illustrating the configuration of a radio frequency module and a communication device according to a first embodiment;

FIG. 2 is a diagram illustrating the configuration of a second acoustic wave filter included in the radio frequency module in FIG. 1;

FIG. 3 is a diagram illustrating the configuration of a vertically coupled acoustic wave filter of the second acoustic wave filter in FIG. 2;

FIG. 4 is a diagram for describing an exemplary positional relationship of components of the radio frequency module in FIG. 1;

FIG. 5 is a diagram for describing an exemplary positional relationship of components of a radio frequency module according to a second embodiment;

FIG. 6 is a diagram for describing an exemplary positional relationship of components of a radio frequency module according to a third embodiment;

FIG. 7 is a diagram for describing an exemplary positional relationship of components of a radio frequency module according to a fourth embodiment;

FIG. 8 is a diagram illustrating the configuration of a low-noise amplifier included in a radio frequency module according to a fifth embodiment;

FIG. 9 is a diagram for describing an exemplary positional relationship of components of a radio frequency module according to fifth and sixth embodiments;

FIG. 10 is a diagram for describing an exemplary positional relationship of components of a radio frequency module according to a seventh embodiment;

FIG. 11 is a diagram for describing an exemplary positional relationship of components of a radio frequency module according to an eighth embodiment;

FIG. 12 is a plan view of a state in which electronic components are disposed in an accommodating recess of a multilayer substrate of a radio frequency module according to a ninth embodiment; and

FIG. 13 is a cross-sectional view along X1-X1 line in FIG. 12.

### DESCRIPTION OF EMBODIMENTS

In the front-end circuit described in Japanese Unexamined Patent Application Publication No. 2021-125775, during a process of connecting the output section of the low-noise amplifier to the RFIC, electrostatic discharge may enter the low-noise amplifier from the output section of the low-noise amplifier. Further, after the output section of the low-noise amplifier is connected to the RFIC, during adjustment of characteristics of the front-end circuit, electrostatic discharge may enter the low-noise amplifier from the output section of the low-noise amplifier. Electrostatic discharge entering the low-noise amplifier through its output section may cause degradation of characteristics of the low-noise amplifier.

In view of the features described above, the present disclosure is directed toward providing a radio frequency module and a communication device which are capable of reducing degradation of characteristics of a low-noise amplifier.

That is, a communication device according to an aspect of the present disclosure includes a radio frequency module and a signal processing circuit. The signal processing circuit is connected to the radio frequency module, and performs signal processing on a radio frequency signal.

A radio frequency module and a communication device according to embodiments of the present disclosure have an advantage of reducing degradation of characteristics of a low-noise amplifier due to electrostatic discharge.

### First Embodiment

A radio frequency module 1 according to a first embodiment will be described in detail by referring to drawings. The drawings used for description in the embodiments are schematic. The ratios of sizes and thicknesses of the components in the drawings do not necessarily reflect actual dimensional ratios.

### (1) Overview

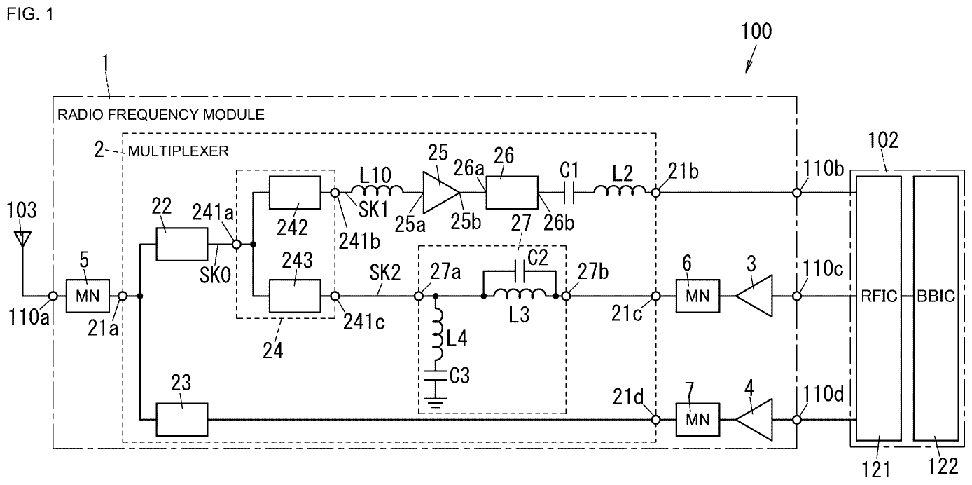

As illustrated in FIG. 1, the radio frequency module 1 according to the first embodiment includes a first acoustic wave filter 24, a low-noise amplifier 25, a second acoustic wave filter 26, and a capacitor C1. The first acoustic wave filter 24 has a first input section 241a and a first output section 241b. The low-noise amplifier 25 has an input section 25a and an output section 25b. The input section 25a of the low-noise amplifier 25 is connected to the first output section 241b of the first acoustic wave filter 24. The second acoustic wave filter 26 has a second input section 26a and a second output section 26b. The second input section 26a of the second acoustic wave filter 26 is connected to the output section 25b of the low-noise amplifier 25. The capacitor C1 is connected to the second output section 26b of the second acoustic wave filter 26.

According to this configuration, the second acoustic wave filter 26 connected to the output section 25b of the low-noise amplifier 25 may reduce electrostatic discharge entering the low-noise amplifier 25 from downstream of the second acoustic wave filter 26 through the output section 25b. Further, the capacitor C1 connected to the second output section 26b of the second acoustic wave filter 26 may further reduce the electrostatic discharge entering the low-noise amplifier 25 through the output section 25b. As a result, degradation of characteristics of the low-noise amplifier 25 due to the electrostatic discharge entering the low-noise amplifier 25 through the output section 25b of the low-noise amplifier 25 may be reduced. That is, degradation of characteristics of the low-noise amplifier 25 due to electrostatic discharge may be reduced.

### (2) Details

### (2-1) Overall Configuration

Referring to FIG. 1, the radio frequency module 1 and a communication device 100 according to the first embodiment will be described. The communication device 100 includes the radio frequency module 1.

As illustrated in FIG. 1, the radio frequency module 1 is capable of supporting, for example, the 4th generation mobile communication (4G) standard and the 5th generation mobile communication (5G) standard. The 4G standard is, for example, Third Generation Partnership Project (3GPP™) or Long Term Evolution standard (LTE™). The 5G standard is, for example, 5G New Radio (NR).

The communication device 100 includes the radio frequency module 1, a signal processing circuit 102, and an antenna 103.

The radio frequency module 1 is configured to amplify a receive signal (radio frequency signal) received by the antenna 103 and output the amplified signal to the signal processing circuit 102. The radio frequency module 1 is configured to amplify a transmit signal (radio frequency signal) output from the signal processing circuit 102 and transmit the amplified signal from the antenna 103. The radio frequency module 1 is controlled, for example, by the signal processing circuit 102.

The signal processing circuit 102, which is connected to the radio frequency module 1, is configured to perform signal processing on a receive signal output from the radio frequency module 1. The signal processing circuit 102 is configured to perform signal processing on a transmit signal output to the radio frequency module 1. The signal processing circuit 102 includes a radio frequency (RF) signal processing circuit 121 and a baseband signal processing circuit 122.

The RF signal processing circuit 121, which is, for example, a radio frequency integrated circuit (RFIC), performs signal processing on radio frequency signals (a transmit signal and a receive signal). The RF signal processing circuit 121 performs signal processing such as down-converting on a receive signal output from the radio frequency module 1, and outputs the processed signal to the baseband signal processing circuit 122. The RF signal processing circuit 121 performs signal processing such as upconverting on a transmit signal output from the baseband signal processing circuit 122, and outputs the processed signal to the radio frequency module 1.

The baseband signal processing circuit 122 is, for example, a baseband integrated circuit (BBIC). The baseband signal processing circuit 122 outputs a receive signal output from the RF signal processing circuit 121 to the outside. Such an output signal (receive signal) may be used, for example, as an image signal for image display or as an audio signal for a call. The baseband signal processing circuit 122 generates a transmit signal from baseband signals (for example, an audio signal and an image signal) input from the outside, and outputs the generated transmit signal to the RF signal processing circuit 121.

### (2-2) Configuration of Radio Frequency Module

The radio frequency module 1 transmits or receives signals in a plurality of frequency bands. In the first embodiment, the radio frequency module 1 transmits or receives signals, for example, in three frequency bands of GNSS (L1), Middle High Band (MHB), and Ultra High Band (UHB). GNSS (L1) is, for example, a frequency band greater than or equal to 1500 MHz and less than or equal to 1600 MHz. MHB is, for example, a frequency band greater than or equal to 1427 MHz and less than or equal to 2690 MHz. UHB is, for example, a frequency band greater than or equal to 3300 MHz and less than or equal to 5000 MHz.

The radio frequency module 1 includes external terminals 110a to 110d, a multiplexer circuit 2, power amplifiers 3 and 4, and matching circuits 5, 6, and 7.

The external terminal 110a is an antenna terminal connected to the antenna 103. The external terminal 110b, which is connected to an input section of the signal processing circuit 102, is an output terminal for outputting a receive signal, which has been processed by the radio frequency module 1, to the input section of the signal processing circuit 102. The external terminals 110c and 110d, which are connected to corresponding output sections of the signal processing circuit 102, are input terminals for receiving transmit signals, which have been processed by the signal processing circuit 102, to the radio frequency module 1.

The multiplexer circuit 2 separates signals in a plurality of frequency bands (for example, GNSS (L1), UHB, and MHB) into signals corresponding to the respective frequency bands. The multiplexer circuit 2 has, for example, the low-noise amplifier 25 compatible with the GNSS (L1) frequency band. The multiplexer circuit 2 includes a common terminal 21a, a plurality of (three in the example in FIG. 1) substrate terminals 21b to 21d, the first acoustic wave filter 24, the second acoustic wave filter 26, an LC filter circuit 27, the low-noise amplifier 25, the capacitor C1, an input-side inductor L10, and an output-side inductor L2.

The common terminal 21a is connected to the antenna terminal 110a. In the example in FIG. 1, the common terminal 21a is connected to the external terminal 110a (that is, the antenna terminal) through the matching circuit 5. The substrate terminals 21b to 21d are directly or indirectly connected to the external terminals 110b to 110d, excluding the external terminal 110a (antenna terminal), among the external terminals 110a to 110d of the radio frequency module 1. The expression “being directly connected” means being connected to an external terminal not through an electronic component. The expression “being indirectly connected” means being connected through an electronic component. In the example in FIG. 1, the substrate terminal 21b is directly connected to the external terminal 110b. The substrate terminal 21c is indirectly connected to the external terminal 110c through the matching circuit 6 and the power amplifier 3. The substrate terminal 21d is indirectly connected to the external terminal 110d through the matching circuit 7 and the power amplifier 4. The substrate terminals 21b to 21d correspond to the frequency bands (for example, GNSS (L1), MHB, and UHB), and carry signals of the respective frequency bands. The substrate terminal 21b corresponds, for example, to the GNSS (L1) frequency band. The substrate terminal 21c corresponds, for example, to the MHB frequency band. The substrate terminal 21d corresponds, for example, to the UHB frequency band.

An LC filter circuit 22 includes one or more inductors and one or more capacitors. The LC filter circuit 22 has an input section and an output section. The input section of the LC filter circuit 22 is connected to the common terminal 21a. The output section of the LC filter circuit 22 is connected to the first input section 241a of the first acoustic wave filter 24, which is described below. The LC filter circuit 22 passes signals in a first frequency band (for example, GNSS (L1)) and a second frequency band (for example, MHB) from among input signals received at the input section of the LC filter circuit 22, and attenuates signals in unnecessary frequency bands (for example, 4.6 GHz and 5.1 GHz).

An LC filter circuit 23 includes one or more inductors and one or more capacitors. The LC filter circuit 23 has an input section and an output section. The input section of the LC filter circuit 23 is connected to the common terminal 21a. The output section of the LC filter circuit 23 is connected to the substrate terminal 21d. The LC filter circuit 23 passes a signal in a third frequency band (for example, UHB) from among input signals received at the input section of the LC filter circuit 23, and attenuates signals in unnecessary frequency bands (for example, 1.5 GHz and 2.5 GHz).

The first acoustic wave filter 24 extracts signals in the first frequency band and the second frequency band from output signals from the LC filter circuit 22; outputs an extracted signal in the first frequency band to a first signal path SK1; and outputs an extracted signal in the second frequency band to a second signal path SK2. The first signal path SK1, through which a signal in the first frequency band passes, is connected to the substrate terminal 21b. The second signal path SK2, through which a signal in the second frequency band passes, is connected to the substrate terminal 21c. The first acoustic wave filter 24 splits a signal path SK0 connected to the output section of the LC filter circuit 23, into the two signal paths (the first signal path SK1 and the second signal path SK2).

The first acoustic wave filter 24 has the first input section 241a, a plurality of (two in the example in FIG. 1) first output sections 241b and 241c, and a plurality of (two in the example in FIG. 1) filters (a first filter 242 and a second filter 243).

The first input section 241a is connected to the output section of the LC filter circuit 22 through the signal path SK0. The first output section 241b is connected to the substrate terminal 21b through the first signal path SK1. The first output section 241c is connected to the substrate terminal 21c through the second signal path SK2.

On the first signal path SK1, the input-side inductor L10, the low-noise amplifier 25, the second acoustic wave filter 26, the capacitor C1, and the output-side inductor L2 are connected. On the second signal path SK2, the LC filter circuit 27 is connected.

The first filter 242 is a ladder filter including, for example, one or more serial resonators and one or more parallel resonators. The first filter 242 has an input section and an output section. The input section of the first filter 242 is connected to the first input section 241a. The output section of the first filter 242 is connected to the first output section 241b. The first output section 241b is one of the two first output sections 241b and 241c. The first filter 242 passes a signal in the first frequency band from among input signals received at the input section of the first filter 242, and attenuates signals in unnecessary frequency bands; and outputs the passed signal from the output section of the first filter 242 to the first output section 241b.

The second filter 243 is a ladder filter including, for example, one or more serial resonators and one or more parallel resonators. The second filter 243 has an input section and an output section. The input section of the second filter 243 is connected to the first input section 241a. The output section of the second filter 243 is connected to the first output section 241c. The first output section 241c is the remaining one of the two first output sections 241b and 241c. The second filter 243 passes a signal in the second frequency band from among input signals received at the input section of the second filter 243, and attenuates signals in unnecessary frequency bands; and outputs the passed signal from the output section of the second filter 243 to the first output section 241c.

The low-noise amplifier 25 is connected to the first output section 241b of the first acoustic wave filter 24 through the input-side inductor L10. The low-noise amplifier 25 has the input section 25a and the output section 25b. The input section 25a is connected to the first output section 241b of the first acoustic wave filter 24 through the input-side inductor L10. The output section 25b is connected to the second input section 26a of the second acoustic wave filter 26. The low-noise amplifier 25 amplifies an input signal received at the input section 25a, and outputs the amplified input signal from the output section 25b to the second acoustic wave filter 26.

The input-side inductor L10 is connected in series between the first output section 241b of the first acoustic wave filter 24 and the input section 25a of the low-noise amplifier 25. The input-side inductor L10 has a first end and a second end. The first end of the input-side inductor L10 is connected to the first output section 241b of the first acoustic wave filter 24. The second end of the input-side inductor L10 is connected to the input section 25a of the low-noise amplifier 25. That is, the input-side inductor L10 is connected to the input side of the low-noise amplifier 25. In the first embodiment, the first filter 242 suppresses a signal in the second frequency band (for example, MHB) entering the first signal path SK1 through the first filter 242. The input-side inductor L10 further suppresses a signal in the second frequency band (for example, MHB) entering the first signal path SK1 through the first filter 242.

The second acoustic wave filter 26 is, for example, a surface acoustic wave (SAW) filter. The second acoustic wave filter 26 has the second input section 26a and the second output section 26b. The second input section 26a is connected to the output section 25b of the low-noise amplifier 25. The second output section 26b is connected to the substrate terminal 21b through the capacitor C1 and the output-side inductor L2. The second acoustic wave filter 26 passes a signal in the first frequency band from among input signals received at the second input section 26a, and attenuates unnecessary signals; and outputs the passed signal from the second output section 26b.

The capacitor C1 is connected to the second output section 26b of the second acoustic wave filter 26. More specifically, the capacitor C1 is connected in series between the second output section 26b of the second acoustic wave filter 26 and the substrate terminal 21b (in the example in FIG. 1, between the output section of the second acoustic wave filter 26 and a first end of the output-side inductor L2 described below). The capacitor C1 has a first end and a second end. The first end of the capacitor C1 is connected to the second output section 26b of the second acoustic wave filter 26. The second end of the capacitor C1 is connected to the substrate terminal 21b through the output-side inductor L2.

The capacitor C1 is a capacitor for electrostatic discharge (ESD) protection. More specifically, the capacitor C1 reduces electrostatic discharge reaching the second acoustic wave filter 26 and the low-noise amplifier 25, the electrostatic discharge having entered the multiplexer circuit 2 through the substrate terminal 21b. Thus, degradation of characteristics of the second acoustic wave filter 26 and the low-noise amplifier 25 due to electrostatic discharge is reduced. Similarly to the capacitor C1, the second acoustic wave filter 26 also has a function of reducing electrostatic discharge reaching the low-noise amplifier 25, the electrostatic discharge having entered the multiplexer circuit 2 through the substrate terminal 21b.

The output-side inductor L2 is connected to the second output section 26b of the second acoustic wave filter 26. That is, the output-side inductor L2 is connected to the output side of the second acoustic wave filter 26. The output-side inductor L2 is connected in series to the capacitor C1. More specifically, the output-side inductor L2 is connected in series between the capacitor C1 and the substrate terminal 21b. The output-side inductor L2 has the first end and a second end. The first end of the output-side inductor L2 is connected to the second end of the capacitor C1. The second end of the output-side inductor L2 is connected to the substrate terminal 21b. The capacitor C1 and the output-side inductor L2 may be arranged in an interchanged manner. The capacitor C1 and the output-side inductor L2 form a matching circuit for impedance matching between the external terminal 110b and the second acoustic wave filter 26.

The LC filter circuit 27 includes one or more (two in the example in FIG. 1) inductors L3 and L4 and one or more (two in the example in FIG. 1) capacitors C2 and C3. The LC filter circuit 27 further includes an input section 27a and an output section 27b. The input section 27a is connected to the first output section 241c of the first acoustic wave filter 24. The first output section 241c is the remaining one of the two first output sections 241b and 241c. The output section 27b is connected to the substrate terminal 21c. The inductor L3 is connected in series to a portion (signal path) between the input section 27a and the output section 27b on the second signal path SK2. The inductor L4 is connected between the ground and a portion (signal path) between the input section 27a and the output section 27b on the second signal path SK2. The capacitor C2 is connected in parallel to the inductor L3. The capacitor C3 is connected in series to the inductor L4. In the example in FIG. 1, the capacitor C3 is connected between the inductor L4 and the ground. The inductor L3 and the capacitor C2 form an attenuation pole for attenuating a signal in an unnecessary frequency band (for example, 3.4 GHz). The inductor L4 and the capacitor C3 form an attenuation pole for attenuating a signal in an unnecessary frequency band (for example, 0.9 GHz).

The power amplifier 3 is connected between the substrate terminal 21c and the external terminal 110c. The power amplifier 3 has an input section and an output section. The input section of the power amplifier 3 is connected to the external terminal 110c. The output section of the power amplifier 3 is connected to the substrate terminal 21c through the matching circuit 6. The power amplifier 3 amplifies an input signal received at the input section of the power amplifier 3, and outputs the amplified input signal to the substrate terminal 21c through the matching circuit 6.

The power amplifier 4 is connected between the substrate terminal 21d and the external terminal 110d. The power amplifier 4 has an input section and an output section. The input section of the power amplifier 4 is connected to the external terminal 110d. The output section of the power amplifier 4 is connected to the substrate terminal 21d through the matching circuit 7. The power amplifier 4 amplifies an input signal received at the input section of the power amplifier 4, and outputs the amplified input signal to the substrate terminal 21d through the matching circuit 7.

The matching circuit 5 is connected between the antenna terminal 110a and the common terminal 21a. The matching circuit 5 performs impedance matching between the antenna terminal 110a and the multiplexer circuit 2. The matching circuit 6 is connected between the output section of the power amplifier 3 and the substrate terminal 21c. The matching circuit 6 performs impedance matching between the power amplifier 3 and the multiplexer circuit 2. The matching circuit 7 is connected between the output section of the power amplifier 4 and the substrate terminal 21d. The matching circuit 7 performs impedance matching between the power amplifier 4 and the multiplexer circuit 2.

### (2-3) Configuration of Second Acoustic Wave Filter

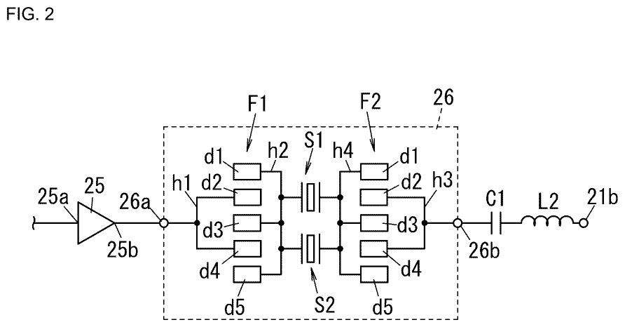

As illustrated in FIG. 2, the second acoustic wave filter 26 includes the second input section 26a, the second output section 26b, one or more (two in the example in FIG. 2) vertically coupled acoustic wave filters F1 and F2, and one or more (two in the example in FIG. 2) resonators S1 and S2.

The second input section 26a is connected to the output section 25b of the low-noise amplifier 25. The second output section 26b is connected to the first end of the capacitor C1.

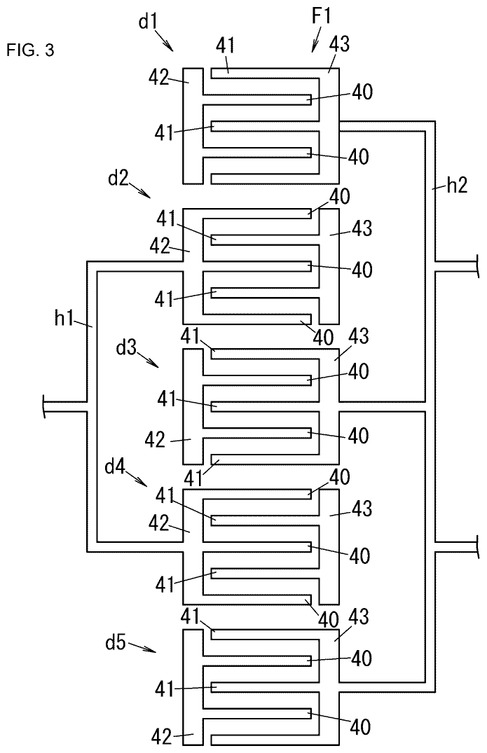

As illustrated in FIG. 3, the vertically coupled acoustic wave filter F1 includes a plurality of (five in the example in FIG. 2) inter digital transducer (IDT) electrodes d1 to d5.

As illustrated in FIG. 3, each of the IDT electrodes d1 to d5 has first electrode fingers 40, second electrode fingers 41, a first busbar 42, and a second busbar 43. The first electrode fingers 40 are arranged in parallel to each other. The second electrode fingers 41 are arranged in parallel to each other. The second electrode fingers 41 are arranged between the first electrode fingers 40. That is, the first electrode fingers 40 and the second electrode fingers 41 are alternately arranged so as to be interdigitated with each other. The first busbar 42 is disposed along one side of the first electrode fingers 40, and is connected to respective ends of the first electrode fingers 40 on the one side. The second busbar 43 is disposed along the other end of the second electrode fingers 41, and is connected to respective ends of the second electrode fingers 41 on the other end.

The IDT electrodes d1 to d5 of the vertically coupled acoustic wave filter F1 are arranged in a line in the direction (the vertical direction on the sheet of FIG. 2) in which the first electrode fingers 40 and the second electrode fingers 41 of the IDT electrodes d1 to d5 are arranged. The first busbars 42 of the even-numbered IDT electrodes d2 and d4 among the IDT electrodes d1 to d5 are connected in common to each other through a wiring line h1, and are connected to the second input section 26a (see FIG. 2). The second busbars 43 of the odd-numbered IDT electrodes d1, d3, and d5 among the IDT electrodes d1 to d5 are connected in common to each other through a wiring line h2, and are connected to first ends of the two resonators S1 and S2 (see FIG. 2), each having the first end and a second end.

Similarly to the vertically coupled acoustic wave filter F1, as illustrated in FIG. 2, the vertically coupled acoustic wave filter F2 also includes a plurality of (five in the example in FIG. 2) IDT electrodes d1 to d5. The configurations of the IDT electrodes d1 to d5 of the vertically coupled acoustic wave filter F2 are the same as those of the IDT electrodes d1 to d5 of the vertically coupled acoustic wave filter F1. Therefore, in the configuration of the IDT electrodes d1 to d5 of the vertically coupled acoustic wave filter F2, the same configurations of the IDT electrodes d1 to d5 of the vertically coupled acoustic wave filter F1 are designated with the same reference numerals for description. The IDT electrodes d1 to d5 of the vertically coupled acoustic wave filter F2 will be described by referring to FIG. 3 which illustrates the vertically coupled acoustic wave filter F1 including the IDT electrodes d1 to d5 having the same configurations.

The IDT electrodes d1 to d5 (see FIG. 3) of the vertically coupled acoustic wave filter F2 are arranged in a line in the direction (the vertical direction on the sheet of FIG. 2) in which the first electrode fingers 40 and the second electrode fingers 41 of the IDT electrodes d1 to d5 are arranged. The first busbars 42 of the even-numbered IDT electrodes d2 and d4 among the IDT electrodes d1 to d5 are connected in common to each other through a wiring line h3, and are connected to the second output section 26b. The second busbars 43 of the odd-numbered IDT electrodes d1, d3, and d5 among the IDT electrodes d1 to d5 are connected in common to each other through a wiring line h4, and are connected to the second ends of the two resonators S1 and S2, each having the first end and the second end.

The two resonators S1 and S2 are connected between the vertically coupled acoustic wave filters F1 and F2. The two resonators S1 and S2 are connected in parallel to each other (see FIG. 2). The two resonators S1 and S2 are serial resonators connected in series to signal paths between the second input section 26a and the second output section 26b. More specifically, the first ends of the two resonators S1 and S2 are connected to the second busbars 43 of the odd-numbered IDT electrodes d1, d3, and d5 of the vertically coupled acoustic wave filter F1 through the wiring line h2. The second ends of the two resonators S1 and S2 are connected to the second busbars 43 of the odd-numbered IDT electrodes d1, d3, and d5 of the vertically coupled acoustic wave filter F2 through the wiring line h4.

In the example in FIG. 2, both the two resonators S1 and S2 are serial resonators. However, one of the two resonators S1 and S2 may be a parallel resonator connected between the wiring line h2 or the wiring line h4 and the ground.

### (2-4) Operation of Radio Frequency Module

Referring to FIG. 1, operation of the radio frequency module 1 will be described.

Operation in a case where a signal in the first frequency band (GNSS (L1)) is received will be described. When the antenna 103 receives a receive signal containing a signal in the first frequency band, the receive signal is sequentially passed through the matching circuit 5, the LC filter circuit 22, the first filter 242, the input-side inductor L10, the low-noise amplifier 25, the second acoustic wave filter 26, the capacitor C1, and the output-side inductor L2, and is output from the external terminal 110b to the signal processing circuit 102. At that time, the LC filter circuit 22, the first filter 242, and the second acoustic wave filter 26 attenuate signals in unnecessary frequency bands other than the first frequency band from the receive signal. Only the signal in the first frequency band is output from the external terminal 110c.

Operation in a case where a signal in the second frequency band (MHB) is transmitted will be described. When a transmit signal containing a signal in the second frequency band is received at the external terminal 110c from the signal processing circuit 102, the transmit signal passes through the power amplifier 3, the matching circuit 6, the LC filter circuit 27, the second filter 243, the LC filter circuit 22, and the matching circuit 5, and is transmitted from the antenna 103 to the outside. At that time, the LC filter circuit 27, the second filter 243, and the LC filter circuit 22 attenuate signals in unnecessary frequency bands other than the second frequency band in the transmit signal. Only the signal in the second frequency band is transmitted from the antenna 103.

A case in which reception of a signal in the first frequency band and transmission of a signal in the second frequency band are performed at the same time will be discussed. In this case, part of the transmit signal in the second frequency band leaks from the output section of the second filter 243 into the input section of the first filter 242, and is then output from the output section of the first filter 242. However, the part of the transmit signal in the second frequency band, which has leaked from the output section of the second filter 243 into the input section of the first filter 242, is attenuated by the first filter 242 and the input-side inductor L10, and the part hardly passes through the first filter 242 and the input-side inductor L10. The first filter 242 and the input-side inductor L10 pass the receive signal in the first frequency band almost without attenuation. Therefore, in the subsequent stage of the input-side inductor L10, only the receive signal in the first frequency band passes, while the part of the transmit signal in the second frequency band does not pass. Therefore, interference between the receive signal in the first frequency band and the transmit signal in the second frequency band is reduced.

Operation in a case where a signal in the third frequency band (UHB) is transmitted will be described. When a transmit signal in the third frequency band is received at the external terminal 110d from the signal processing circuit 102, the transmit signal passes through the power amplifier 4, the matching circuit 7, the LC filter circuit 23, and the matching circuit 5, and is then output from the antenna 103 to the outside.

A case in which electrostatic discharge flows into the external terminal 110b from the signal processing circuit 102 will be discussed. In this case, the capacitor C1 reduces electrostatic discharge entering the second acoustic wave filter 26 and the low-noise amplifier 25. Thus, degradation of characteristics of each of the second acoustic wave filter 26 and the low-noise amplifier 25 due to electrostatic discharge is reduced. The second acoustic wave filter 26 reduces electrostatic discharge entering the low-noise amplifier 25. Thus, degradation of characteristics of the low-noise amplifier 25 due to electrostatic discharge is further reduced.

(2-5) Positional Relationship between Second Acoustic Wave Filter, Capacitor, and Output-Side Inductor

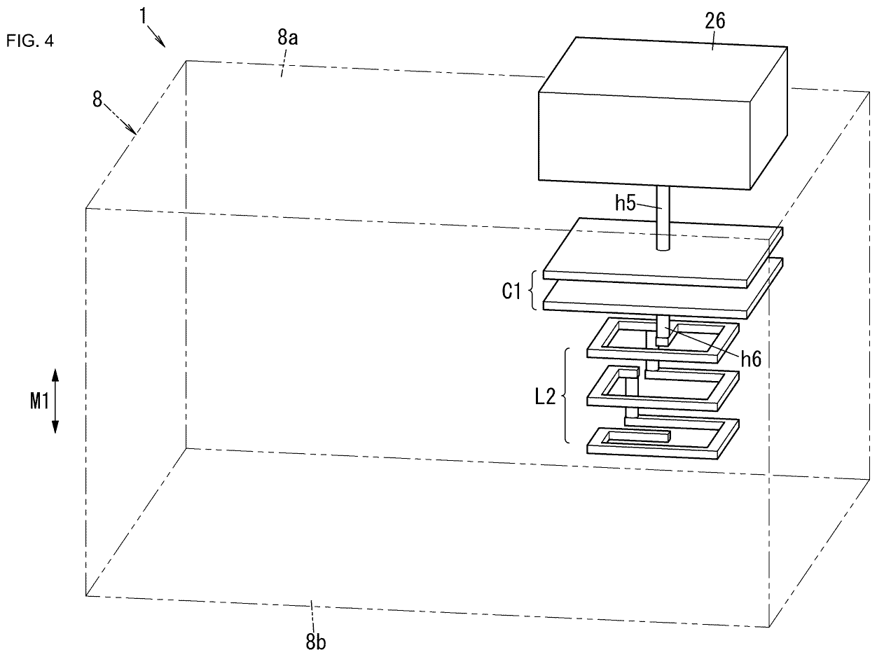

Referring to FIG. 4, the positional relationship between the second acoustic wave filter 26, the capacitor C1, and the output-side inductor L2 will be described. As illustrated in FIG. 4, the radio frequency module 1 further includes a multilayer substrate 8.

The multilayer substrate 8 is a substrate on or in which electronic components included in the radio frequency module 1 are disposed (mounted). In the example in FIG. 4, only the second acoustic wave filter 26, the capacitor C1, and the output-side inductor L2 are illustrated among the electronic components described above. The multilayer substrate 8 is, for example, planar. The multilayer substrate 8 is, for example, a low temperature co-fired ceramics (LTCC) substrate. The multilayer substrate 8 is not limited to an LTCC, and may be, for example, a resin multilayer substrate, a printed wiring board, or a high temperature co-fired ceramics (HTCC) substrate.

The multilayer substrate 8 includes, for example, dielectric layers and conductive layers. Each of the conductive layers is disposed between dielectric layers. That is, the dielectric layers and the conductive layers are laminated alternately in the thickness direction M1 of the multilayer substrate 8. The conductive layers are formed in predetermined pattens defined for the respective layers. Inside the multilayer substrate 8, via conductors are disposed. The via conductors form signal lines each connecting two different conductive layers, and form signal lines connecting conductive layers to pads disposed on the principal surfaces (a first principal surface 8a and a second principal surface 8b described below) of the multilayer substrate 8 on both sides. The dielectric layers are formed, for example, of ceramic. The conductive layers, the via conductors, and the pads are formed, for example, of copper or copper alloy.

The multilayer substrate 8 has the first principal surface 8a and the second principal surface 8b. The first principal surface 8a and the second principal surface 8b are principal surfaces opposite each other in the thickness direction M1 of the multilayer substrate 8.

In the radio frequency module 1, the second acoustic wave filter 26 is disposed on the first principal surface 8a of the multilayer substrate 8. The capacitor C1 and the output-side inductor L2 are disposed inside the multilayer substrate 8 (e.g., between the first and second principal surfaces 8a and 8b of the multilayer substrate 8). The output section of the second acoustic wave filter 26 is connected to the first end of the capacitor C1 through a signal line h5. The second end of the capacitor C1 is connected to the first end of the output-side inductor L2 through a signal line h6. The signal lines h5 and h6 extend in the thickness direction M1 of the multilayer substrate 8. The signal lines h5 and h6 are formed of via conductors in the multilayer substrate 8.

The capacitor C1 overlaps the second acoustic wave filter 26 in the thickness direction M1 of the multilayer substrate 8. The expression “the capacitor C1 overlaps the second acoustic wave filter 26 in the thickness direction M1 of the multilayer substrate 8” refers to a state in which at least a part of the capacitor C1 (the entirety in the example in FIG. 4) overlaps the second acoustic wave filter 26 in the thickness direction M1 of the multilayer substrate 8. Accordingly, the signal line h5 is shortened.

At least a part (the entirety in the example in FIG. 4) of the output-side inductor L2 overlaps the second acoustic wave filter 26 in the thickness direction M1 of the multilayer substrate 8. At least a part (the entirety in the example in FIG. 4) of the output-side inductor L2 overlaps the capacitor C1 in the thickness direction M1 of the multilayer substrate 8. In the example in FIG. 4, the output-side inductor L2 is disposed on the opposite side of the capacitor C1 from the second acoustic wave filter 26. Accordingly, the signal line h6 is shortened. Thus, the signal lines h5 and h6 are shortened (e.g., a length of each of the signal lines h5 and h6 in the thickness direction M1 of the multilayer substrate 8 is reduced due to a shorter distance between the overlapping components), thereby reducing signal loss in the signal lines h5 and h6. Accordingly, degradation of the noise figure (NF) characteristics of the low-noise amplifier 25 may be reduced.

### (2-6) Effects

The radio frequency module 1 according to the first embodiment includes the first acoustic wave filter 24, the low-noise amplifier 25, the second acoustic wave filter 26, and the capacitor C1 (see FIG. 1). The first acoustic wave filter 24 has the first input section 241a and the first output section 241b. The low-noise amplifier 25 has the input section 25a and the output section 25b. The input section 25a is connected to the first output section 241b of the first acoustic wave filter 24. The second acoustic wave filter 26 has the second input section 26a and the second output section 26b. The second input section 26a is connected to the output section 25b of the low-noise amplifier 25. The capacitor C1 is connected to the second output section 26b of the second acoustic wave filter 26.

According to the configuration, the second acoustic wave filter 26 connected to the output section 25b of the low-noise amplifier 25 may reduce electrostatic discharge entering the low-noise amplifier 25 through the output section 25b from the downstream side of the second acoustic wave filter 26. Further, the capacitor C1 connected to the second output section 26b of the second acoustic wave filter 26 may further reduce the electrostatic discharge entering the low-noise amplifier 25 through the output section 25b. These may reduce degradation of characteristics of the low-noise amplifier 25 due to the electrostatic discharge entering the low-noise amplifier 25 through the output section 25b. That is, degradation of characteristics of the low-noise amplifier 25 due to electrostatic discharge may be reduced.

In addition, the radio frequency module 1 according to the first embodiment includes the multiplexer circuit 2 (see FIG. 1). The multiplexer circuit 2 includes the first acoustic wave filter 24, the low-noise amplifier 25, and the second acoustic wave filter 26. According to this configuration, the second acoustic wave filter 26 included in the multiplexer circuit 2 may reduce degradation of characteristics of the low-noise amplifier 25 due to electrostatic discharge.

The radio frequency module 1 according to the first embodiment includes the output-side inductor L2 (see FIG. 1). The output-side inductor L2 is connected to the second output section 26b of the second acoustic wave filter 26. According to this configuration, electrostatic discharge entering the low-noise amplifier 25 through the output section 25b may be further reduced. Accordingly, degradation of characteristics of the low-noise amplifier 25 due to electrostatic discharge may be further reduced.

In the radio frequency module 1 according to the first embodiment, the output-side inductor L2 is connected in series to the capacitor C1 (see FIG. 1). According to this configuration, electrostatic discharge entering the low-noise amplifier 25 through the output section 25b may be effectively reduced. Thus, degradation of characteristics of the low-noise amplifier 25 due to electrostatic discharge may be effectively reduced.

In the radio frequency module 1 according to the first embodiment, the second acoustic wave filter 26 includes the vertically coupled acoustic wave filters F1 and F2 (see FIG. 2). The vertically coupled acoustic wave filters F1 and F2 each have the IDT electrodes d1 to d5. Each of the IDT electrodes d1 to d5 has the first electrode fingers 40, the second electrode fingers 41, the first busbar 42, and the second busbar 43 (see FIG. 3). The first electrode fingers 40 are arranged in parallel with each other and spaced apart. The second electrode fingers 41 are interdigitated between the first electrode fingers 40. The first busbar 42 is connected to respective ends of the first electrode fingers 40 on a first side. The second busbar 43 is connected to respective ends of the second electrode fingers 41 on a second side (that is, the opposite side from the first side). The IDT electrodes d1 to d5 are arranged in a line in the direction in which the first electrode fingers 40 and the second electrode fingers 41 are arranged. Among the IDT electrodes d1 to d5, the first busbars 42 of the even-numbered IDT electrodes d2 and d4 are connected in common to each other. The second busbars 43 of the odd-numbered IDT electrodes d1, d3, and d4 are connected in common to each other.

According to this configuration, even in a configuration in which the second acoustic wave filter 26 includes the vertically coupled acoustic wave filters F1 and F2, degradation of characteristics of the low-noise amplifier 25 due to electrostatic discharge may be reduced.

The radio frequency module 1 according to the first embodiment includes the multilayer substrate 8 (see FIG. 4). The multilayer substrate 8 has the first principal surface 8a and the second principal surface 8b opposite each other. The second acoustic wave filter 26 is disposed on the first principal surface 8a of the multilayer substrate 8. The capacitor C1 is disposed inside the multilayer substrate 8. The capacitor C1 overlaps the second acoustic wave filter 26 in the thickness direction M1 of the multilayer substrate 8. According to this configuration, the signal line h5 between the second acoustic wave filter 26 and the capacitor C1 may be shortened. Therefore, signal loss in the signal line h5 may be reduced. Accordingly, degradation of the NF characteristics of the low-noise amplifier 25 may be reduced.

The communication device 100 according to the first embodiment includes the radio frequency module 1 and the signal processing circuit 102 (see FIG. 1). The signal processing circuit 102, which is connected to the radio frequency module 1, performs signal processing on a radio frequency signal. According to this configuration, the communication device 100 having the effects of the radio frequency module 1 may be provided.

### (3) Modified Example

In the first embodiment, for the second frequency band and the third frequency band, the radio frequency module 1 is assumed to include only the configurations (the matching circuits 6 and 7 and the power amplifiers 3 and 4) for transmission between transmission and reception. However, for the second frequency band and the third frequency band, in the first embodiment, the radio frequency module 1 may be assumed to include only configurations for reception instead of transmission, or may be assumed to include configurations for both transmission and reception.

### Second Embodiment

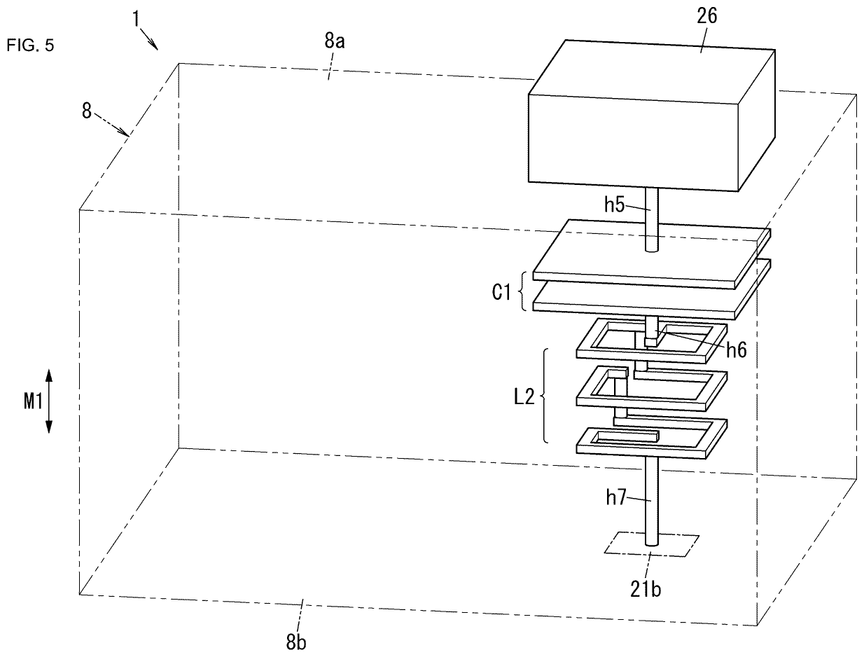

Referring to FIG. 5, the radio frequency module 1 according to a second embodiment will be described.

### (1) Configuration

As illustrated in FIG. 5, the configuration of the radio frequency module 1 according to the second embodiment is substantially the same as that of the radio frequency module 1 according to the first embodiment except that the positional relationship of the substrate terminal 21b is further limited.

As illustrated in FIG. 5, in the second embodiment, the substrate terminal 21b is disposed on the second principal surface 8b of the multilayer substrate 8. The substrate terminal 21b is connected to the second end of the output-side inductor L2 through a signal line h7. The signal line h7 extends in the thickness direction M1 of the multilayer substrate 8. The signal line h7 is formed of a via conductor in the multilayer substrate 8.

The substrate terminal 21b overlaps the second acoustic wave filter 26 and the capacitor C1 in the thickness direction M1 of the multilayer substrate 8. The expression “the substrate terminal 21b overlaps the second acoustic wave filter 26 and the capacitor C1 in the thickness direction M1 of the multilayer substrate 8” refers to a state in which at least a part (the entirety in the example in FIG. 5) of the substrate terminal 21b overlaps at least a part (both in the example in FIG. 5) of the second acoustic wave filter 26 and the capacitor C1 in the thickness direction M1 of the multilayer substrate 8. Thus, signal lines (for example, the signal lines h5, h6, and h7 as a whole) between the second acoustic wave filter 26 and the substrate terminal 21b and between the capacitor C1 and the substrate terminal 21b may be shortened. This may further reduce degradation of the NF characteristics of the low-noise amplifier 25 compared with a case in which the substrate terminal 21b does not overlap the second acoustic wave filter 26 and the capacitor C1 in the thickness direction M1 of the multilayer substrate 8.

The substrate terminal 21b further overlaps the output-side inductor L2 in the thickness direction M1 of the multilayer substrate 8. The expression “the substrate terminal 21b overlaps the output-side inductor L2 in the thickness direction M1 of the multilayer substrate 8” refers to a state in which at least a part (the entirety in the example in FIG. 5) of the substrate terminal 21b overlaps the output-side inductor L2 in the thickness direction M1 of the multilayer substrate 8. Thus, the signal line h7 may be shortened. Since the signal line h7 may be shortened, signal loss in the signal line h7 may be reduced. This may further reduce degradation of the NF characteristics of the low-noise amplifier 25 compared with the case of the first embodiment (FIG. 4).

### (2) Effects

The radio frequency module 1 according to the second embodiment includes the substrate terminal 21b (see FIG. 5). The substrate terminal 21b is disposed on the second principal surface 8b of the multilayer substrate 8. The substrate terminal 21b overlaps the second acoustic wave filter 26 and the capacitor C1 in the thickness direction M1 of the multilayer substrate 8. According to this configuration, the signal line h7 between the capacitor C1 and the substrate terminal 21b may be shortened. Therefore, signal loss in the signal line h7 may be reduced. This may reduce degradation of the NF characteristics of the low-noise amplifier 25.

### Third Embodiment

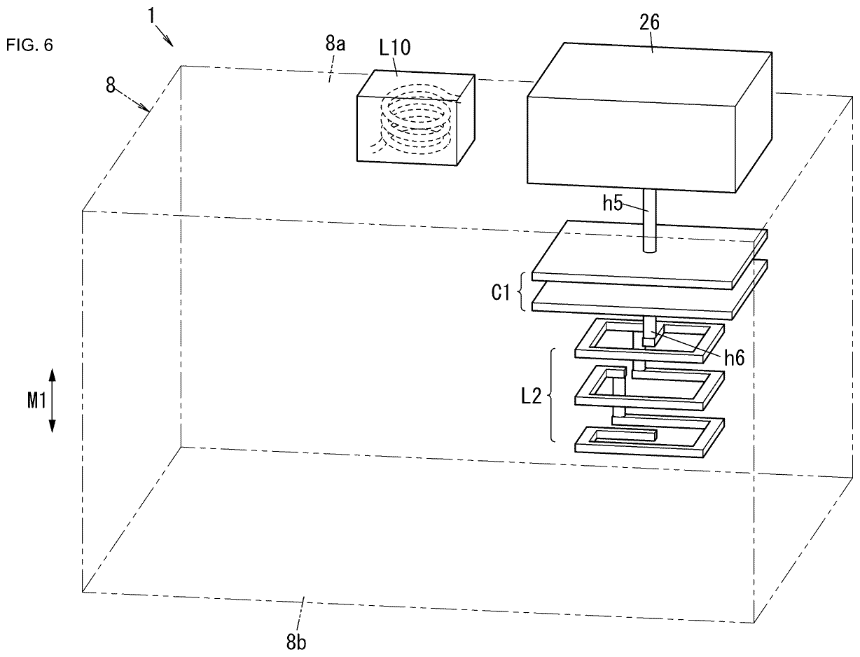

Referring to FIG. 6, the radio frequency module 1 according to a third embodiment will be described.

### (1) Configuration

As illustrated in FIG. 6, the configuration of the radio frequency module 1 according to the third embodiment is substantially the same as that of the radio frequency module 1 according to the first embodiment except that the positional relationship of the input-side inductor L10 and the output-side inductor L2 is further limited.

As illustrated in FIG. 6, in the third embodiment, the input-side inductor L10 is disposed on the first principal surface 8a of the multilayer substrate 8. More specifically, the input-side inductor L10 is formed as a surface mount device (e.g., the input-side inductor L10 may be formed on an outer surface of the multilayer substrate 8 to be external with respect to the multilayer substrate 8). The output-side inductor L2 is disposed inside the multilayer substrate 8 as in the case of the first embodiment (FIG. 4).

The winding direction of the input-side inductor L10 is different from that of the output-side inductor L2. More specifically, in the example in FIG. 6, the winding direction of the input-side inductor L10 is a winding about a virtual axis perpendicular to the first principal surface 8a of the multilayer substrate 8, and counterclockwise when the input-side inductor L10 is viewed from above the first principal surface 8a. In the example in FIG. 6, the winding direction of the output-side inductor L2 is a winding about a virtual axis (that is, a virtual axis perpendicular to the first principal surface 8a) parallel to the thickness direction M1 of the multilayer substrate 8, and is clockwise when the output-side inductor L2 is viewed from above the first principal surface 8a.

The expression “the winding direction of the input-side inductor L10 is different from that of the output-side inductor L2” refers to both a first case and a second case described below. In the first case, one of the input-side inductor L10 and the output-side inductor L2 winds vertically; the other winds horizontally. Vertical winding refers to a case in which the center axis of an inductor is parallel to the thickness direction M1 of the multilayer substrate 8; horizontal winding refers to a case in which the center axis of an inductor is orthogonal to the thickness direction M1 of the multilayer substrate 8. The second case is the case in which both the input-side inductor L10 and the output-side inductor L2 wind vertically or horizontally, and in which the winding directions are opposite to each other. The example in FIG. 6 corresponds to the second case.

### (2) Effects

The radio frequency module 1 according to the third embodiment includes the output-side inductor L2 (see FIG. 6). The radio frequency module 1 includes the input-side inductor L10 (see FIG. 6). The input-side inductor L10 is connected between the first output section 241b of the first acoustic wave filter 24 and the input section 25a of the low-noise amplifier 25. The winding direction of the input-side inductor L10 is different from that of the output-side inductor L2 (see FIG. 6). According to this configuration, since the winding direction of the input-side inductor L10 is different from that of the output-side inductor L2, magnetic field coupling between the input-side inductor L10 and the output-side inductor L2 is suppressed. This may suppress an output signal from the second filter 243 leaking into the input side of the low-noise amplifier 25, thereby suppressing unnecessary oscillation or the like of the low-noise amplifier 25.

### Fourth Embodiment

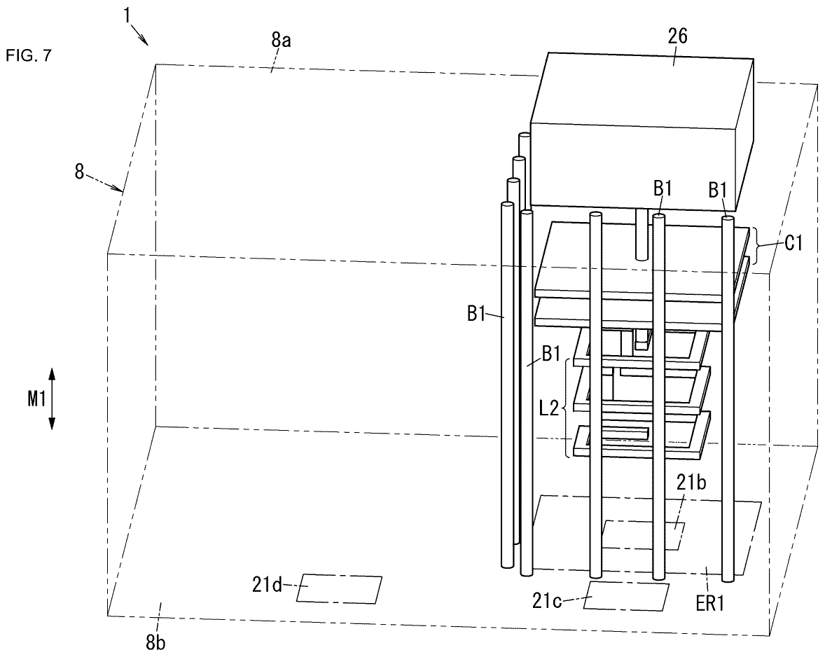

Referring to FIG. 7, the radio frequency module 1 according to a fourth embodiment will be described. 1 Configuration

As illustrated in FIG. 7, the configuration of the radio frequency module 1 according to the fourth embodiment is substantially the same as that of the radio frequency module 1 (see FIG. 5) according to the second embodiment except that, in plan view in the thickness direction M1 of the multilayer substrate 8, via conductors B1 are arranged between an area ER1, which includes the substrate terminal 21b (first substrate terminal) through which a signal in the first frequency band passes, and the other substrate terminals 21c and 21d.

More specifically, as illustrated in FIG. 7, in the fourth embodiment, the substrate terminals 21b to 21c are disposed on the second principal surface 8b of the multilayer substrate 8. The substrate terminals 21b to 21d are directly or indirectly connected to the external terminals 110b to 110d, excluding the external terminal 110a (that is, the antenna terminal), among the external terminal 110a to 110b (see FIG. 1). In the example in FIG. 1, the substrate terminal 21b is directly connected to the external terminal 110b. That is, the substrate terminal 21b is connected to the external terminal 110b not through an electronic component. The substrate terminal 21c is indirectly connected to the external terminal 110c. That is, the substrate terminal 21c is connected to the external terminal 110c through electronic components (the matching circuit 6 and the power amplifier 3). The substrate terminal 21d is indirectly connected to the external terminal 110d. That is, the substrate terminal 21d is connected to the external terminal 110d through electronic components (the matching circuit 7 and the power amplifier 4).

The expression “a substrate terminal is directly connected to an external terminal” means that the substrate terminal is connected to the external terminal not through an electronic component. The expression “a substrate terminal is indirectly connected to an external terminal” means that the substrate terminal is connected to the external terminal through an electronic component.

In the fourth embodiment, as in the second embodiment, at least part (the entirety in the example in FIG. 7) of the substrate terminal 21b overlaps at least one (both in the example in FIG. 7) of the second acoustic wave filter 26 and the capacitor C1 in the thickness direction M1 of the multilayer substrate 8. In the fourth embodiment, as in the second embodiment, at least part (the entirety in the example in FIG. 7) of the substrate terminal 21b further overlaps the output-side inductor L2 in the thickness direction M1 of the multilayer substrate 8.

In the fourth embodiment, the second principal surface 8b of the multilayer substrate 8 has the area ER1. In plan view in the thickness direction M1 of the multilayer substrate 8, the second acoustic wave filter 26 and the capacitor C1 are disposed inside the area ER1. In the fourth embodiment, in plan view in the thickness direction M1 of the multilayer substrate 8, the output-side inductor L2 is further disposed inside the area ER1. For example, in plan view in the thickness direction M1 of the multilayer substrate 8, the area ER1 overlaps (e.g., surrounds a perimeter of) an entire area of each of the second acoustic wave filter 26, the capacitor C1, and the output-side inductor L2.

The via conductors B1 are disposed inside the multilayer substrate 8, and are electrically connected to the ground. The via conductors B1 extend between the second principal surface 8b and the first principal surface 8a of the multilayer substrate 8. For example, the via conductors B1 extend linearly in the thickness direction M1 of the multilayer substrate 8. In plan view in the thickness direction M1 of the multilayer substrate 8, the via conductors B1 are arranged between the area ER1 and the substrate terminals 21c and 21d, excluding the substrate terminal 21b, among the substrate terminals 21b to 21d. The via conductors B1 are disposed along the periphery of the area ER1 (e.g., the via conductors B1 may surround a perimeter of the area ER1 and the substrate terminal 21b while separating the area ER1 with the substrate terminal 21b from the substrate terminals 21c and 21d). The via conductors B1 improve isolation (insulation isolation) between the substrate terminal 21b and the other substrate terminals 21c and 21d.

### (2) Effects

The radio frequency module 1 according to the fourth embodiment includes the multiplexer circuit 2 (see FIG. 1) and the via conductors B1 (see FIG. 7). The multiplexer circuit 2 includes the first acoustic wave filter 24, the low-noise amplifier 25, the second acoustic wave filter 26, and the capacitor C1. The via conductors B1 are disposed inside the multilayer substrate 8 (see FIG. 7), and are connected to the ground. The multiplexer circuit 2 includes the substrate terminals 21b to 21d (see FIG. 1). The substrate terminals 21b to 21d include the substrate terminal 21b (first substrate terminal). The substrate terminals 21b to 21d are directly or indirectly connected to the external terminals 110b to 110d, excluding the antenna terminal 110a, among the external terminals 110a to 110d of the radio frequency module 1 (see FIG. 1). The substrate terminals 21b to 21d are disposed on the second principal surface 8b of the multilayer substrate 8 (see FIG. 7). The second principal surface 8b of the multilayer substrate 8 has the area ER1 (see FIG. 7). In plan view in the thickness direction M1 of the multilayer substrate 8, the second acoustic wave filter 26, the capacitor C1, and the substrate terminal 21b are disposed inside the area ER1 (see FIG. 7). In plan view in the thickness direction M1 of the multilayer substrate 8, the via conductors B1 are arranged between the area ER1 and the substrate terminals 21c and 21d, excluding the substrate terminal 21b, among the substrate terminals 21b to 21d (see FIG. 7).

This configuration improves isolation (insulation isolation) between the substrate terminal 21b and the other substrate terminals 21c and 21d, among the substrate terminals 21b to 21d of the multiplexer circuit 2.

### Fifth Embodiment

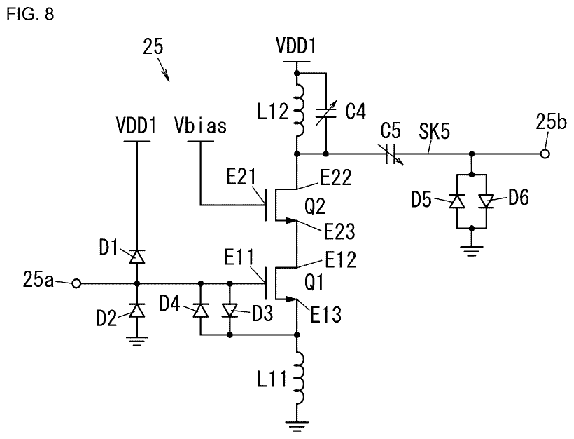

Referring to FIG. 8, the radio frequency module 1 according to a fifth embodiment will be described.

### (1) Configuration

As illustrated in FIG. 8, the configuration of the radio frequency module 1 according to the fifth embodiment is substantially the same as that of the radio frequency module 1 according to the first embodiment except that the arrangement of the components of the low-noise amplifier 25 is limited.

As illustrated in FIG. 8, in the fifth embodiment, the low-noise amplifier 25 includes the input section 25a, the output section 25b, a first semiconductor switch Q1, a second semiconductor switch Q2, a first inductor L11, a second inductor L12, and variable capacitors C4 and C5.

The first semiconductor switch Q1 is, for example, an N-channel metal oxide semiconductor field-effect transistor (MOSFET). The first semiconductor switch Q1 has a first control electrode E11 (for example, the gate) and two first main electrodes E12 and E13 (the drain and the source). The second semiconductor switch Q2 is, for example, an N-channel MOSFET. The second semiconductor switch Q2 has a second control electrode E21 (for example, the gate) and two second main electrodes E22 and E23 (the drain and the source).

The first semiconductor switch Q1 and the second semiconductor switch Q2 are connected in series to each other between a power supply VDD1 and the ground. More specifically, the first main electrode E12, which is one of the first main electrodes of the first semiconductor switch Q1, is connected to the second main electrode E23, which is one of the second main electrodes of the second semiconductor switch Q2. The remaining first main electrode E13 of the first semiconductor switch Q1 is connected to the ground through the first inductor L11. The first control electrode E11 of the first semiconductor switch Q1 is connected to the input section 25a. The second main electrode E23, which one of the second main electrodes of the second semiconductor switch Q2, is connected to the first main electrode E12, which is one of the first main electrodes of the first semiconductor switch Q1. The remaining second main electrode E22 of the second semiconductor switch Q2 is connected to the power supply VDD1 through the second inductor L12. The second control electrode E21 of the second semiconductor switch Q2 receives a bias voltage Vbias, and the second semiconductor switch Q2 is always ON.

Diodes D1 and D2 are, for example, diodes for reverse-voltage protection for the input section 25a. The diode D1 is reversely connected between the input section 25a and the power supply VDD1. That is, the cathode of the diode D1 is connected to the power supply VDD1 (that is, the high voltage side); the anode of the diode D1 is connected to the input section 25a (that is, the low voltage side). The diode D2 is reversely connected between the input section 25a and the ground. That is, the cathode of the diode D2 is connected to the input section 25a (high voltage side); the anode of the diode D1 is connected to the ground (that is, the low voltage side).

Diodes D3 and D4 are, for example, diodes for reverse-voltage protection for the first control electrode E11 of the first semiconductor switch Q1. The diodes D3 and D4 are connected in parallel to each other and in opposite directions between the first control electrode E11 of the first semiconductor switch Q1 and the remaining first main electrode E13.

Diodes D5 and D6 are, for example, diodes for ESD protection against electrostatic discharge entering the low-noise amplifier 25 through the output section 25b. The diodes D5 and D6 are connected in parallel to each other and in opposite directions between the output section 25b and the ground.

The variable capacitor C4 is connected in parallel to the second inductor L12.

The variable capacitor C5 is, for example, a capacitor for ESD protection against electrostatic discharge entering the low-noise amplifier 25 through the output section 25b. The variable capacitor C5 is connected in series to a signal path between the output section 25b and the remaining second main electrode E22 of the second semiconductor switch Q2. More specifically, the variable capacitor C5 has a first end and a second end. The first end of the variable capacitor C5 is connected to the remaining second main electrode E22 (the second main electrode on the second inductor L12 side) between the two second main electrodes E22 and E23 of the second semiconductor switch Q2. The second end of the variable capacitor C5 is connected to the output section 25b.

### (2) Positional Relationship of Components of Low-Noise Amplifier

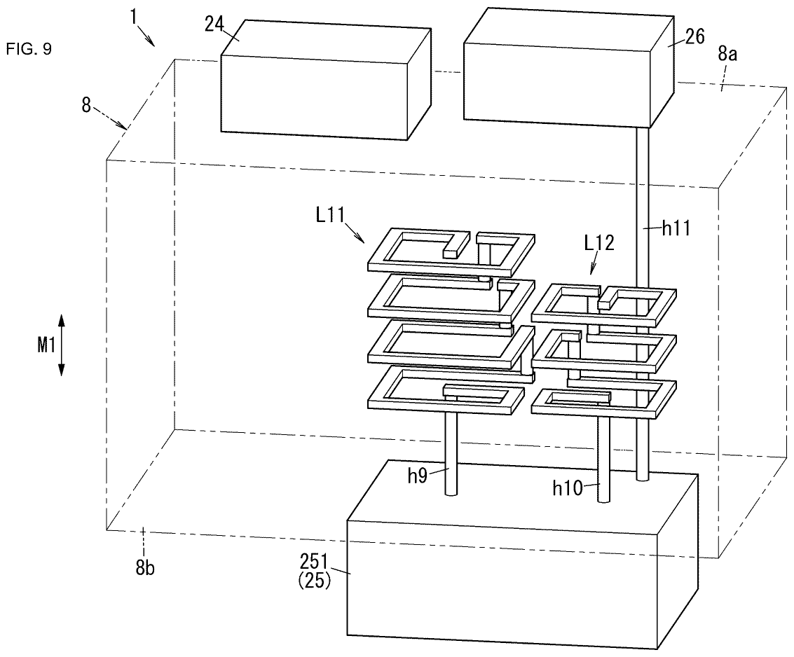

Referring to FIG. 9, the positional relationship of components of the low-noise amplifier 25 will be described. As illustrated in FIG. 9, the first acoustic wave filter 24 and the second acoustic wave filter 26 are disposed on the first principal surface 8a of the multilayer substrate 8.

Among the components of the low-noise amplifier 25, the electronic components (the first semiconductor switch Q1, the second semiconductor switch Q2, the diodes D1 to D6, and the variable capacitors C4 and C5) other than the first inductor L11 and the second inductor are included in a chip 251. The chip 251 is a semiconductor chip (also referred to as an integrated circuit (IC) chip). The chip 251 is disposed on the second principal surface 8b of the multilayer substrate 8 (e.g., outside the chip 251). The first inductor L11 and the second inductor L12 are disposed inside the multilayer substrate 8 (e.g., between the first and second principal surfaces 8a and 8b of the multilayer substrate 8). One end of the first inductor L11 is connected to an external electrode of the chip 251 through a signal line h9. One end of the second inductor L12 is connected to a different external electrode of the chip 251 through a signal line h10. The signal lines h9 and h10 are formed of via conductors in the multilayer substrate 8.

In plan view in the thickness direction M1 of the multilayer substrate 8, at least part (the entirety of both in the example in FIG. 9) of at least one (both in the example in FIG. 9) of the first inductor L11 and the second inductor L12 overlaps the chip 251. Thus, at least one (both in the example in FIG. 9) of the signal lines h9 and h10 may be shortened. In the example in FIG. 9, the signal lines h9 and h10 extend in the thickness direction M1 of the multilayer substrate 8, thereby having the shortest lengths. This may reduce parasitic components (for example, parasitic inductance and parasitic capacitance) generated in at least one (both in the example in FIG. 9) of the signal lines h9 and h10. Accordingly, the NF characteristics of the low-noise amplifier 25 may be improved.

The first end of the second acoustic wave filter 26 is connected to an external electrode of the chip 251 through a signal line h11. The signal line h11 is formed of a via conductor in the multilayer substrate 8. In plan view in the thickness direction M1 of the multilayer substrate 8, at least part of the second acoustic wave filter 26 overlaps the chip 251. Accordingly, the signal line h11 may be shortened. In the example in FIG. 9, the signal line h11 extends in the thickness direction M1 of the multilayer substrate 8, thereby having the shortest length. This may reduce parasitic components (for example, parasitic inductance and parasitic capacitance) generated in the signal line h11. Accordingly, the NF characteristics of the low-noise amplifier 25 may be improved.

### (3) Effects

In the radio frequency module 1 according to the fifth embodiment, the low-noise amplifier 25 (more specifically, the chip 251) is disposed on the second principal surface 8b of the multilayer substrate 8 (see FIG. 9). According to this configuration, degradation of characteristics of the low-noise amplifier 25 due to electrostatic discharge may be reduced in a configuration in which the low-noise amplifier 25 is disposed on the second principal surface 8b of the multilayer substrate 8.

The radio frequency module 1 according to the fifth embodiment includes the multilayer substrate 8 (see FIG. 9). The multilayer substrate 8 has the first principal surface 8a and the second principal surface 8b opposite each other. The low-noise amplifier 25 has the first semiconductor switch Q1, the second semiconductor switch Q2, the first inductor L11, and the second inductor L12 (see FIG. 8). The first semiconductor switch Q1 has the first control electrode E11 and the two first main electrodes E12 and E13. The second semiconductor switch Q2 has the second control electrode E21 and the two second main electrodes E22 and E23. The second main electrode E23, which is one of the second main electrodes of the second semiconductor switch Q2, is connected to the first main electrode E12, which is one of the first main electrodes of the first semiconductor switch Q1. The first inductor L11 is connected between the ground and the remaining first main electrode E3 of the first semiconductor switch Q1. The second inductor L12 is connected between the power supply VDD1 and the remaining second main electrode E22 of the second semiconductor switch Q2. The input section 25a of the low-noise amplifier 25 is connected to the first control electrode E11 of the first semiconductor switch Q1. The output section 25b of the low-noise amplifier 25 is connected to the remaining second main electrode E22 of the second semiconductor switch Q2. Among the components of the low-noise amplifier 25, the electronic components (in the example in FIG. 9, the first semiconductor switch Q1, the second semiconductor switch Q2, the capacitors C2 and C3, and the diodes D1 to D6) other than the first inductor L11 and the second inductor L12 are included in the chip 251 (see FIG. 9). The chip 251 is disposed on one (the second principal surface 8b in the example in FIG. 9) of the first principal surface 8a and the second principal surface 8b of the multilayer substrate 8. The first inductor L11 and the second inductor L12 are disposed inside the multilayer substrate 8 (see FIG. 9). In the thickness direction M1 of the multilayer substrate 8, at least one of the first inductor L11 and the second inductor L12 overlaps the chip 251 (see FIG. 9).

According to this configuration, the signal line h9 between the first semiconductor switch Q1 and the first inductor L11 and the signal line h10 between the second semiconductor switch Q2 and the second inductor L12 may be shortened. Therefore, in a configuration in which the first inductor L11 and the second inductor L12 are disposed inside the multilayer substrate 8, parasitic components (for example, parasitic inductance and parasitic capacitance) generated in the signal lines h9 and h10 may be reduced.

In the radio frequency module 1 according to the fifth embodiment, the low-noise amplifier 25 includes the variable capacitor C5 (see FIG. 8). The variable capacitor C5 is connected in series to a signal path between the output section 25b of the low-noise amplifier 25 and the remaining second main electrode E22 of the second semiconductor switch Q2. According to this configuration, the variable capacitor C5 may reduce degradation of characteristics of the first semiconductor switch Q1 and the second semiconductor switch Q2 due to electrostatic discharge entering the low-noise amplifier 25 through the output section 25b. Accordingly, degradation of characteristics of the low-noise amplifier 25 due to electrostatic discharge may be reduced.

### (4) Modified Example

In the fifth embodiment, the case in which the chip 251 is disposed on the second principal surface 8b of the multilayer substrate 8 is described as an example. However, the chip 251 may be disposed on the first principal surface 8a of the multilayer substrate 8. Also in this case, at least part of at least one of the first inductor L11 and the second inductor L12 is disposed so as to overlap the chip 251 in plan view in the thickness direction M1 of the multilayer substrate 8. Accordingly, as in the fifth embodiment, at least one of the signal lines h9 and h10 may be shortened, thereby improving the NF characteristics of the low-noise amplifier 25.

### Sixth Embodiment

Referring to FIG. 9, the radio frequency module 1 according to a sixth embodiment will be described. In the description below, the same configurations as those in the fifth embodiment are designated with the same reference numerals, and description may be avoided.

### (1) Configuration

The radio frequency module 1 according to the sixth embodiment has a limited relationship between the winding direction of the first inductor L11 and that of the second inductor L12.

In the sixth embodiment, the winding direction of the first inductor L11 is different from that of the second inductor L12. More specifically, in the example in FIG. 9, the winding direction of the first inductor L11 is a winding about a virtual axis parallel to the thickness direction M1 of the multilayer substrate 8, and is, for example, counterclockwise when the first inductor L11 is viewed from above the first principal surface 8a side of the multilayer substrate 8. In the example in FIG. 9, the winding direction of the second inductor L12 is a winding about a virtual axis parallel to the thickness direction M1 of the multilayer substrate 8, and is, for example, clockwise when the first inductor L11 is viewed from above the first principal surface 8a side of the multilayer substrate 8.

The expression “the winding direction of the first inductor L11 is different from that of the second inductor L12” refers to both a first case and a second case described below. In the first case, one of the first inductor L11 and the second inductor L12 has a vertical winding; the other has a horizontal winding. The definition of the vertical winding and the horizontal winding is the same as that in the third embodiment. In the second case, both the input-side inductor L10 and the output-side inductor L2 have a vertical winding or a horizontal winding, and the winding directions are opposite to each other. The example in FIG. 9 corresponds to the second case.

### (2) Effects

In the radio frequency module 1 according to the sixth embodiment, the winding direction of the first inductor L11 is different from that of the second inductor L12 (see FIG. 9). According to this configuration, since the winding direction of the first inductor L11 is different from that of the second inductor L12, degradation of the Q value due to magnetic field coupling between the first inductor L11 and the second inductor L12 may be suppressed. Accordingly, degradation of the NF characteristics of the low-noise amplifier 25 may be reduced.

### Seventh Embodiment

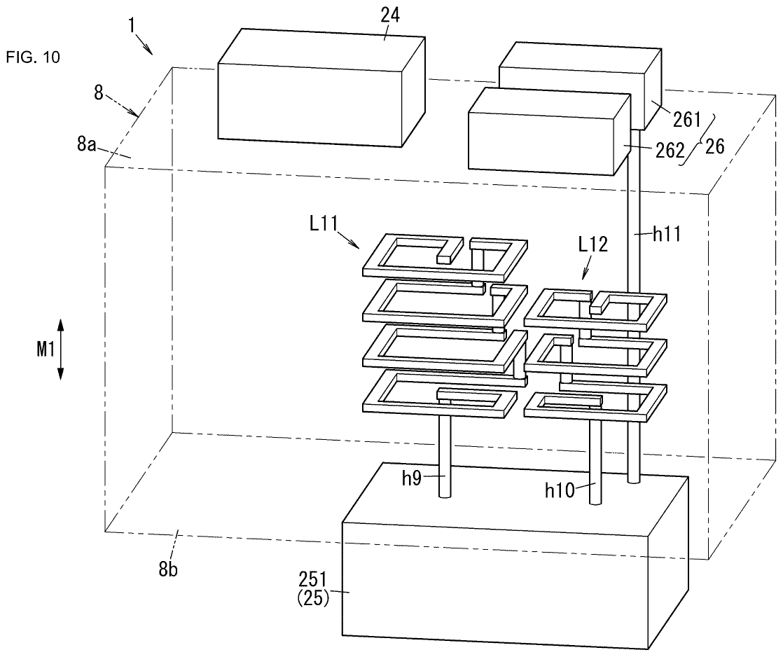

Referring to FIG. 10, the radio frequency module 1 according to a seventh embodiment will be described.

### (1) Configuration

As illustrated in FIG. 10, the configuration of the radio frequency module 1 according to the seventh embodiment is substantially the same as that of the radio frequency module 1 according to the sixth embodiment except that the second acoustic wave filter 26 is configured to be divided into a first chip 261 and a second chip 262.

The second acoustic wave filter 26 according to the seventh embodiment (hereinafter simply referred to as the “second acoustic wave filter 26”) is configured in substantially the same manner as that of the second acoustic wave filter 26 according to the sixth embodiment (that is, the second acoustic wave filter 26 illustrated in FIG. 2) except that the second acoustic wave filter 26 is configured to be divided into the first chip 261 and the second chip 262 different from each other. Among the components of the second acoustic wave filter 26, the electronic components other than the one or more (two in the example in FIG. 2) vertically coupled acoustic wave filters F1 and F2 (that is, the one or more (two in the example in FIG. 2) resonators S1 and S2), as well as the second input section 26a and the second output section 26b, are included in the first chip 261. Among the components of the second acoustic wave filter 26, the one or more (two in the example in FIG. 2) vertically coupled acoustic wave filters F1 and F2 are included in the second chip 262.

In plan view in the thickness direction M1 of the multilayer substrate 8, at least part of the first chip 261 overlaps the low-noise amplifier 25. This may shorten the signal line h11 between the output section of the low-noise amplifier 25 and an input section of the first chip 261. Therefore, also in the seventh embodiment, as in the sixth embodiment, parasitic components (for example, parasitic inductance and parasitic capacitance) parasitically present in the signal line h11 may be reduced. As a result, the NF characteristics of the low-noise amplifier 25 may be improved.

### (2) Effects

In the radio frequency module 1 according to the seventh embodiment, the second acoustic wave filter 26 includes the vertically coupled acoustic wave filters F1 and F2 (see FIG. 2). The second acoustic wave filter 26 further includes the resonators S1 and S2 (see FIG. 2). The resonators S1 and S2 are included in the first chip 261 (see FIG. 10). The vertically coupled acoustic wave filters F1 and F2 are included in the second chip 262 (see FIG. 10) different from the first chip 261. According to this configuration, as in the sixth embodiment, degradation of characteristics of the low-noise amplifier 25 due to electrostatic discharge may be reduced in a configuration in which the second acoustic wave filter 26 is divided into the first chip 261 and the second chip 262.

### Eighth Embodiment

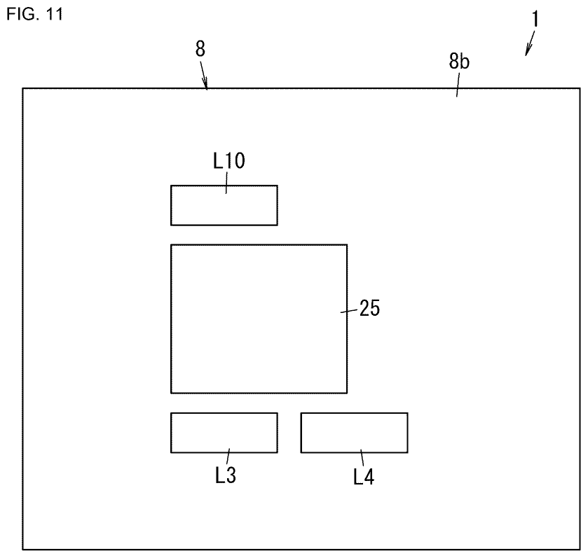

Referring to FIG. 11, the radio frequency module 1 according to an eighth embodiment will be described. The configuration of the radio frequency module 1 according to the eighth embodiment is the same as that of the radio frequency module 1 according to the first embodiment. Therefore, the configuration of the radio frequency module 1 according to the eighth embodiment will be described by referring to FIG. 1.

### (1) Configuration

As illustrated in FIG. 11, the configuration of the radio frequency module 1 according to the eighth embodiment is substantially the same as that of the radio frequency module 1 according to the first embodiment except that the positional relationship of inductors (the input-side inductor L10 and the inductors L3 and L4) connected to the plurality of (two in the example in FIG. 1) first output sections 241b and 241c (see FIG. 1) of the first acoustic wave filter 24 (see FIG. 1) is limited.

As illustrated in FIG. 11, in the eighth embodiment, the low-noise amplifier 25 is disposed on the second principal surface 8b of the multilayer substrate 8.

As described in the first embodiment, the first output section 241b, which is one of the first output sections of the first acoustic wave filter 24, is connected to the input-side inductor L10 (see FIG. 1). The other first output section 241c of the first acoustic wave filter 24 is connected to the inductors L3 and L4. The inductors L3 and L4 are inductors different from the input-side inductor L10 (i.e., additional inductors).

As illustrated in FIG. 11, the input-side inductor L10 and the inductors L3 and L4 are disposed on one of the first principal surface 8a and the second principal surface 8b (the second principal surface 8b in the example in FIG. 11) of the multilayer substrate 8. The low-noise amplifier 25 is disposed between the input-side inductor L10 and the inductors L3 and L4. In other words, the input-side inductor L10 and the inductors L3 and L4 are disposed on both sides of the low-noise amplifier 25. This improves isolation (insulation isolation) characteristics between the first signal path SK1 (see FIG. 1), which is connected to the first output section 241b which is one of the first output sections, and the second signal path SK2 (see FIG. 1), which is connected to the other first output section 241c. The first signal path SK1 is a signal path through which a signal in the first frequency band (GNSS (L1)) passes. The second signal path SK2 is a signal path through which a signal in the second frequency band (MHB) passes. As a result, for example, degradation of characteristics of the low-noise amplifier 25 due to a state in which a transmit signal in the second frequency band which passes through the second signal path SK2 is coupled with the input-side inductor L10 may be reduced.

### (2) Effects

The radio frequency module 1 according to the eighth embodiment includes the multilayer substrate 8, the input-side inductor L10, and the inductors L3 and L4 which are different from the input-side inductor L10 (see FIG. 1). The multilayer substrate 8 has the first principal surface 8a and the second principal surface 8b opposite each other. The first acoustic wave filter 24 has the first output sections 241b and 241c including the first output section 241b. The input-side inductor L10 is connected between the first output section 241b, which is one of the first output sections 241b and 241c, and the input section 25a of the low-noise amplifier 25. The inductors L3 and L4, which are different from the input-side inductor L10, are connected to the first output section 241c which is different from the first output section 241b which is one of the first output sections 241b and 241c. The input-side inductor L10 and the inductors L3 and L4, which are different from the input-side inductor L10, are disposed on one of the first principal surface 8a and the second principal surface 8b (the second principal surface 8b in the example in FIG. 11) of the multilayer substrate 8 (see FIG. 11). The low-noise amplifier 25 is disposed between the input-side inductor L10 and the inductors L3 and L4, which are different from the input-side inductor L10, on one of the principal surfaces (the second principal surface 8b) (see FIG. 11).

This configuration improves isolation (insulation isolation) characteristics between the first signal path SK1 (see FIG. 1), which is connected to the first output section 241b which is one of the first output sections, and the second signal path SK2 (see FIG. 1), which is connected to the different first output section 241c.

### (3) Modified Example

A modified example of the eighth embodiment will be described.

In the eighth embodiment, the case in which the low-noise amplifier 25, the input-side inductor L10, and the inductors L3 and L4 are disposed on the second principal surface 8b of the multilayer substrate 8 is described as an example. However, the low-noise amplifier 25, the input-side inductor L10, and the inductors L3 and L4 may be disposed on the first principal surface 8a of the multilayer substrate 8. This modified example may exert substantially the same effects as those in the eighth embodiment.

### Ninth Embodiment

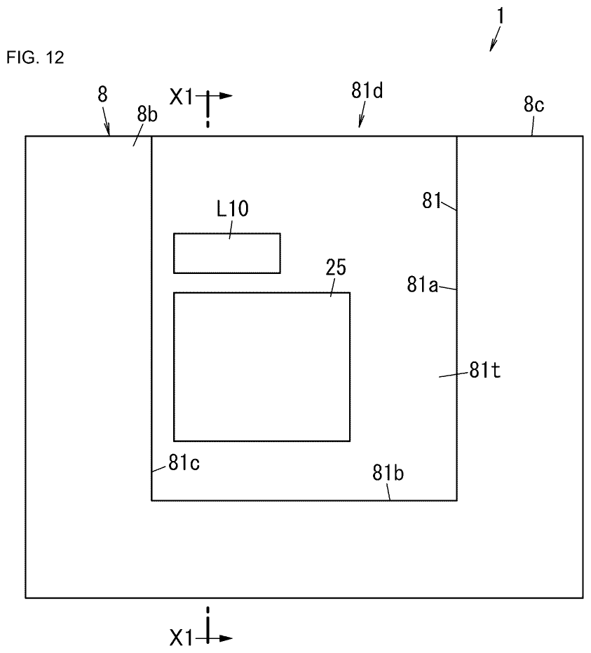

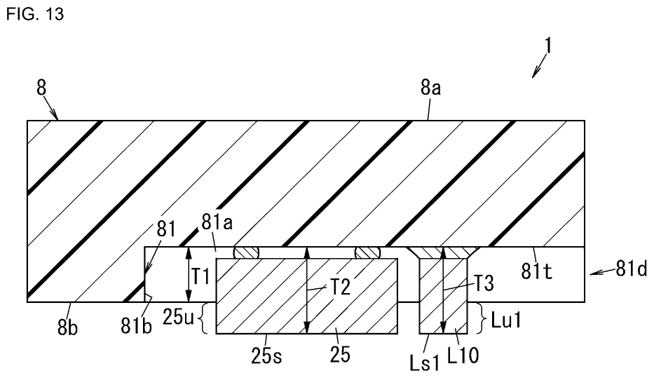

Referring to FIGS. 12 and 13, the radio frequency module 1 according to a ninth embodiment will be described. 1 Configuration

As illustrated in FIGS. 12 and 13, the configuration of the radio frequency module 1 according to the ninth embodiment is substantially the same as that of the radio frequency module 1 according to the first embodiment except that the input-side inductor L10 and the low-noise amplifier 25 are disposed on a bottom surface 81t of an accommodating recess 81 on the second principal surface 8b of the multilayer substrate 8.

As illustrated in FIGS. 12 and 13, in the ninth embodiment, the second principal surface 8b of the multilayer substrate 8 has the accommodating recess 81. The accommodating recess 81 is, for example, rectangular in plan view. In the example in FIGS. 12 and 13, the accommodating recess 81 has the bottom surface 81t, a plurality of (three in the example in FIG. 12) side surfaces 81a to 81c, and a side opening 81d. The side opening 81d is open in a portion of a periphery 8c of the multilayer substrate 8. In the example in FIG. 13, the depth T1 of the accommodating recess 81 is less than the height T2 of the low-noise amplifier 25 and the height T3 of the input-side inductor L10. However, the depth T1 of the accommodating recess 81 may be greater than the height T2 of the low-noise amplifier 25 and the height T3 of the input-side inductor L10.

The height T2 of the low-noise amplifier 25 is a length from the bottom surface 81t to a surface 25s (that is, the surface opposite the bottom surface 81t) of the low-noise amplifier 25. The height T3 of the input-side inductor L10 is a length from the bottom surface 81t to a surface Ls1 (That is, the surface opposite the bottom surface 81t) of the input-side inductor L10.

In the ninth embodiment, the low-noise amplifier 25 and the input-side inductor L10 are disposed on the bottom surface 81t of the accommodating recess 81 on the second principal surface 8b of the multilayer substrate 8. In the example in FIG. 13, a projecting portion 25u of the low-noise amplifier 25 projects from (e.g., beyond) the second principal surface 8b of the multilayer substrate 8. A projecting portion Lu1 of the input-side inductor L10 projects from the second principal surface 8b of the multilayer substrate 8. The low-noise amplifier 25 and the input-side inductor L10 are disposed on the bottom surface 81t of the accommodating recess 81 on the second principal surface 8b of the multilayer substrate 8, thereby shortening the projecting portions 25u and Lu1. This contributes to a reduction in profile of the radio frequency module 1.

### (2) Effects

The radio frequency module 1 according to the ninth embodiment includes the multilayer substrate 8 (see FIG. 12) and the input-side inductor L10 (see FIG. 1). The multilayer substrate 8 has the first principal surface 8a and the second principal surface 8b opposite each other. The input-side inductor L10 is connected between the first output section 241b of the first acoustic wave filter 24 and the input section 25a of the low-noise amplifier 25. One of the first principal surface 8a and the second principal surface 8b (the second principal surface 8b in the example in FIGS. 12 and 13) of the multilayer substrate 8 has the accommodating recess 81. The low-noise amplifier 25 and the input-side inductor L10 are disposed on the bottom surface 81t of the accommodating recess 81 (see FIGS. 12 and 13). This configuration may reduce the profile of the radio frequency module 1.

### (3) Modified Examples

Modified examples of the ninth embodiment will be described.

### (3-1) First Modified Example

In the ninth embodiment, the case in which the depth T1 of the accommodating recess 81 is less than the height T2 of the low-noise amplifier 25 and the height T3 of the input-side inductor L10 is described as an example. However, the depth T1 of the accommodating recess 81 may be greater than the height T2 of the low-noise amplifier 25 and the height T3 of the input-side inductor L10.

### (3-2) Second Modified Example

In the ninth embodiment, the accommodating recess 81 is assumed to have the side opening 81d. However, the accommodating recess 81 may have a side surface instead of the side opening 81d. In this case, the accommodating recess 81 is surrounded by four side surfaces. This modified example exerts substantially the same effects as those of the ninth embodiment.

The first to ninth embodiments and the modified examples thereof may be implemented in combination.

What is claimed is:

1. A radio frequency module, comprising:
a first acoustic wave filter that has a first input section and a first output section;
a low-noise amplifier that has an input section and an output section, the input section of the low-noise amplifier being connected to the first output section of the first acoustic wave filter;
a second acoustic wave filter that has a second input section and a second output section, the second input section of the second acoustic wave filter being connected to the output section of the low-noise amplifier; and
a capacitor connected to the second output section of the second acoustic wave filter.

2. The radio frequency module according to claim 1, further comprising a multiplexer circuit, the multiplexer circuit including the first acoustic wave filter, the low-noise amplifier, and the second acoustic wave filter.

3. The radio frequency module according to claim 1, further comprising an output-side inductor connected to the second output section of the second acoustic wave filter.

4. The radio frequency module according to claim 3, wherein the output-side inductor is connected in series to the capacitor.

5. The radio frequency module according to claim 3, further comprising an input-side inductor connected between the first output section of the first acoustic wave filter and the input section of the low-noise amplifier,
wherein the input-side inductor has a winding direction different from a winding direction of the output-side inductor.

6. The radio frequency module according to claim 1, wherein:
the second acoustic wave filter includes one or more vertically coupled acoustic wave filters,
the one or more vertically coupled acoustic wave filters have a plurality of IDT electrodes,
each of the plurality of IDT electrodes includes:
a plurality of first electrode fingers arranged in parallel and spaced apart from each other;
a plurality of second electrode fingers interdigitated between the plurality of first electrode fingers;
a first busbar connected to respective ends of the plurality of first electrode fingers on a first side; and
a second busbar connected to respective ends of the plurality of second electrode fingers on a second side,
the plurality of IDT electrodes are arranged in a line in a direction in which the plurality of first electrode fingers and the plurality of second electrode fingers are arranged, and
among the plurality of IDT electrodes, first busbars of even-numbered IDT electrodes are connected in common to each other, and second busbars of odd-numbered IDT electrodes are connected in common to each other.

7. The radio frequency module according to claim 6, wherein:
the second acoustic wave filter further includes one or more resonators,
the one or more resonators are included in a first chip, and
the one or more vertically coupled acoustic wave filters are included in a second chip different from the first chip.

8. The radio frequency module according to claim 1, further comprising a multilayer substrate having a first principal surface and a second principal surface opposite each other,
wherein the second acoustic wave filter is disposed on the first principal surface of the multilayer substrate,
wherein the capacitor is disposed inside the multilayer substrate, and
wherein the capacitor overlaps the second acoustic wave filter in a thickness direction of the multilayer substrate.

9. The radio frequency module according to claim 8, further comprising a substrate terminal disposed on the second principal surface of the multilayer substrate,
wherein the substrate terminal overlaps the second acoustic wave filter and the capacitor in the thickness direction of the multilayer substrate.

10. The radio frequency module according to claim 9, further comprising:
a multiplexer circuit including the first acoustic wave filter, the low-noise amplifier, the second acoustic wave filter, and the capacitor; and
a plurality of via conductors disposed inside the multilayer substrate and connected to a ground,
wherein the multiplexer circuit includes a plurality of substrate terminals that include a first substrate terminal which is the substrate terminal and that are each directly or indirectly connected to an external terminal among a plurality of external terminals of the radio frequency module excluding an antenna terminal,
wherein the plurality of substrate terminals are disposed on the second principal surface of the multilayer substrate,
wherein the second principal surface of the multilayer substrate has an area,
wherein the second acoustic wave filter, the capacitor, and the first substrate terminal are disposed inside the area in a plan view in the thickness direction of the multilayer substrate, and
wherein, in the plan view in the thickness direction of the multilayer substrate, the plurality of via conductors are arranged between the area and a substrate terminal among the plurality of substrate terminals excluding the first substrate terminal.

11. The radio frequency module according to claim 8, wherein the low-noise amplifier is disposed on the second principal surface of the multilayer substrate.

12. The radio frequency module according to claim 1, further comprising:
a multilayer substrate that has a first principal surface and a second principal surface opposite each other;
an input-side inductor; and
an additional inductor different from the input-side inductor,
wherein the first acoustic wave filter has a plurality of first output sections including the first output section,
wherein the input-side inductor is connected between the input section of the low-noise amplifier and one of the plurality of first output sections,
wherein the additional inductor is connected to another of the plurality of first output sections,
wherein the input-side inductor and the additional inductor are disposed on one of the first principal surface and the second principal surface of the multilayer substrate, and
wherein the low-noise amplifier is disposed between the input-side inductor and the additional inductor on the one of the first principal surface and the second principal surface.

13. The radio frequency module according to claim 1, further comprising:
a multilayer substrate that has a first principal surface and a second principal surface opposite each other; and
an input-side inductor connected between the first output section of the first acoustic wave filter and the input section of the low-noise amplifier,
wherein one of the first principal surface and the second principal surface of the multilayer substrate has an accommodating recess, and
wherein the low-noise amplifier and the input-side inductor are disposed on a bottom surface of the accommodating recess.

14. The radio frequency module according to claim 1, further comprising a multilayer substrate that has a first principal surface and a second principal surface opposite each other,
wherein the low-noise amplifier includes:
a first semiconductor switch that has a first control electrode and two first main electrodes;
a second semiconductor switch that has a second control electrode and two second main electrodes, one of the second main electrodes being connected to one of the first main electrodes of the first semiconductor switch;
a first inductor connected between a remaining one of the first main electrodes of the first semiconductor switch and a ground; and
a second inductor connected between a remaining one of the second main electrodes of the second semiconductor switch and a power supply,
wherein the input section of the low-noise amplifier is connected to the first control electrode of the first semiconductor switch,
wherein the output section of the low-noise amplifier is connected to the remaining second main electrode of the second semiconductor switch,
wherein an electronic component of the low-noise amplifier is included in a chip, the electronic component being neither the first inductor nor the second inductor,
wherein the chip is disposed on one of the first principal surface and the second principal surface of the multilayer substrate,
wherein the first inductor and the second inductor are disposed inside the multilayer substrate, and
wherein at least one of the first inductor and the second inductor overlaps the chip in a thickness direction of the multilayer substrate.

15. The radio frequency module according to claim 14, wherein:
the low-noise amplifier further includes a variable capacitor, and
the variable capacitor is connected in series to a signal path between the remaining second main electrode of the second semiconductor switch and the output section of the low-noise amplifier.

16. The radio frequency module according to claim 14, wherein the first inductor has a winding direction different from a winding direction of the second inductor.

17. A communication device, comprising:
the radio frequency module according to claim 1; and
a signal processing circuit that is connected to the radio frequency module and that is configured to perform signal processing on a radio frequency signal.
